(19) United States
(12) Patent Application Publication
(10) Pub. No.: US 2024/0363546 A1
(43) Pub. Date: Oct. 31, 2024

(54) HIGH-FREQUENCY MODULE

(71) Applicant: Murata Manufacturing Co., Ltd., Nagaokakyo-shi (JP)

(72) Inventors: Michiharu YOKOYAMA, Nagaokakyo-shi (JP); Takaya NEMOTO, Nagaokakyo-shi (JP); Hideki UEDA, Nagaokakyo-shi (JP)

(73) Assignee: Murata Manufacturing Co., Ltd., Nagaokakyo-shi (JP)

(21) Appl. No.: 18/769,482

(22) Filed: Jul. 11, 2024

Related U.S. Application Data
(63) Continuation of application No. PCT/JP2022/041395, filed on Nov. 7, 2022.

(30) Foreign Application Priority Data
Jan. 17, 2022 (JP) 2022-005059

(51) Int. Cl. H01L 23/552; H01L 23/00; H01L 23/31; H01L 23/538; H01L 25/10; H01Q 1/22

(52) U.S. Cl. CPC H01L 23/552; H01L 23/3135; H01L 23/538; H01L 24/16; H01L 25/105; H01Q 1/2283; H01L 2224/16227

(57) ABSTRACT

Electronic components are included in each one of submodules. Each electronic component includes inner terminals. A first support member covers and supports, the electronic components so as to expose the inner terminals. A second support member supports the submodules. Each one of the submodules includes outer terminals, and the outer terminals are coupled to respective inner terminals and exposed from the second support member. At least one of the submodules has a first conductive film formed on at least part of the first support member.

### CROSS-REFERENCE TO RELATED APPLICATIONS

This application is a continuation of international application no. PCT/JP2022/041395, filed Nov. 7, 2022, and which claims priority to Japanese application no. 2022-005059, filed Jan. 17, 2022. The entire contents of both prior applications are hereby incorporated by reference.

### TECHNICAL FIELD

The present disclosure relates to a high-frequency module that includes multiple electronic components.

### BACKGROUND ART

A technique of mounting multiple integrated-circuit devices onto an interposer and sealing the devices with resin is known. The size and height reduction of mobile communication terminals demands the size and height reduction of components included therein.

### SUMMARY

### Technical Problem

A high-frequency module, in which multiple devices are mounted onto an interposer and the devices are sealed with resin, faces difficulties in height reduction due to the difficulties of reducing the thickness of the interposer. In addition, when a device generating switching noise or multiple high-frequency devices are mounted on a common interposer, electromagnetic interference tends to occur between these devices. An exemplary object of the present disclosure is to provide a high-frequency module that can reduce the height and also can reduce electromagnetic interference.

### Solution to Problem

According to an aspect of the present disclosure, a high-frequency module includes submodules, a second support member, and outer terminals. Each one of the submodules includes electronic components each of which includes inner terminals. Each one of the submodules also includes a first support member covering, and thereby supporting, the electronic components so as to expose the inner terminals. The second support member covers, and thereby supports, the submodules. The outer terminals are coupled to respective ones of the inner terminals and exposed from the second support member. At least one of the submodules has a first conductive film formed on at least part of the first support member.

### Advantageous Effects

The inner terminals of the electronic components are coupled to the outer terminals, and the outer terminals are exposed from the second support member. Accordingly, the high-frequency module can be mounted onto another substrate using exposed outer terminals. No interposer is interposed between the electronic components and the other substrate, which leads to the height reduction. The first conductive film disposed on one of the submodules serves as an electromagnetic shielding film and thereby reduces the electromagnetic interference between the submodules.

### BRIEF DESCRIPTION OF DRAWINGS

FIG. 1A is a cross-sectional view illustrating a high-frequency module according to a first exemplary embodiment.

FIG. 1B is another cross-sectional view illustrating the high-frequency module of FIG. 1A and a module substrate.

FIG. 2A is a cross-sectional view illustrating a manufacturing process of a submodule included in the high-frequency module of the first exemplary embodiment.

FIG. 2B is another cross-sectional view illustrating a manufacturing process of a submodule included in the high-frequency module of the first exemplary embodiment.

FIG. 2C is a further cross-sectional view illustrating a manufacturing process of a submodule included in the high-frequency module of the first exemplary embodiment.

FIG. 2D is a still further cross-sectional view illustrating a manufacturing process of a submodule included in the high-frequency module of the first exemplary embodiment.

FIG. 2E is another cross-sectional view of the submodule.

FIG. 3A is cross-sectional view illustrating a manufacturing process of the high-frequency module of the first exemplary embodiment.

FIG. 3B is another cross-sectional view illustrating a manufacturing process of the high-frequency module of the first exemplary embodiment.

FIG. 3C is a further cross-sectional view illustrating a manufacturing process of the high-frequency module of the first exemplary embodiment.

FIG. 4 is a cross-sectional view illustrating a high-frequency module according to a second exemplary embodiment.

FIG. 5A is a cross-sectional view illustrating a high-frequency module according to a third exemplary embodiment.

FIG. 5B is a cross-sectional view illustrating a high-frequency module according to a variation of the third exemplary embodiment.

FIG. 6 is a cross-sectional view illustrating a high-frequency module according to a fourth exemplary embodiment.

FIG. 7A is cross-sectional view illustrating a high-frequency module according to variations of the fourth exemplary embodiment.

FIG. 7B is another cross-sectional view illustrating a high-frequency module according to variations of the fourth exemplary embodiment.

FIG. 8 is a cross-sectional view illustrating a high-frequency module and a module substrate according to a fifth exemplary embodiment.

FIG. 9 is a cross-sectional view illustrating a high-frequency module and a module substrate according to a sixth exemplary embodiment.

FIG. 10 is a cross-sectional view illustrating a high-frequency module and a module substrate according to a variation of the sixth exemplary embodiment.

FIG. 11 is a cross-sectional view illustrating a high-frequency module and a module substrate according to a seventh exemplary embodiment.

FIG. 12A is a cross-sectional view illustrating a high-frequency module according to an eighth exemplary embodiment.

FIG. 12B is a schematic equivalent circuit diagram of the high-frequency module of the eighth exemplary embodiment.

FIG. 13A is a bottom view of a high-frequency module according to a ninth exemplary embodiment.

FIG. 13B is a bottom view of a high-frequency module according to a variation of the ninth exemplary embodiment.

FIG. 14A is a cross-sectional view of a high-frequency module according to a tenth exemplary embodiment.

FIG. 14B is a cross-sectional view of a high-frequency module according to a variation of the tenth exemplary embodiment.

FIG. 15A is cross-sectional view illustrating high-frequency modules according to other variations of the tenth exemplary embodiment.

FIG. 15B is another cross-sectional view illustrating high-frequency modules according to other variations of the tenth exemplary embodiment.

### DESCRIPTION OF EMBODIMENTS

### First Embodiment

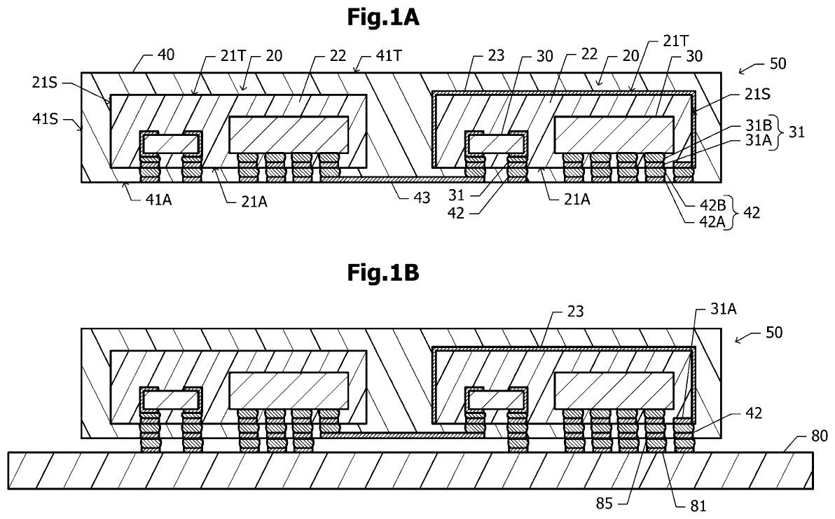

A high-frequency module according to a first exemplary embodiment will be described with reference to FIGS. 1A to 3C. FIG. 1A is a cross-sectional view illustrating the high-frequency module of the first exemplary embodiment.

A high-frequency module 50 of the first exemplary embodiment includes multiple submodules 20. Each submodule 20 includes multiple electronic components 30 and a first support member 22 that is made of resin and covers and supports the electronic components 30.

Each electronic component 30 includes multiple inner terminals 31 that are exposed at one surface of the submodule 20. The surface of the submodule 20 at which the inner terminals 31 are exposed is referred to as a “first surface 21A”. The first surface 21A is a substantially flat surface formed of a surface of the first support member 22 and exposed surfaces of respective first electrodes 31A. The first support member 22 includes a top surface 21T facing opposite to the first surface 21A and side surfaces 21S connecting the first surface 21A and the top surface 21T.

The electronic components 30 are discrete components, such as semiconductor integrated circuits and surface-mount type inductors or capacitors. For example, the submodule 20 has at least one function, such as an RF front-end function or a power management function.

Each inner terminal 31 includes two layers, in other words, a first electrode 31A made of, for example, copper (Cu) and a solder 31B. First electrodes 31A are exposed at the first surface 21A of the submodule 20. In at least one of the submodules 20 (for example, the submodule 20 on the right hand side in FIG. 1A), the top surface 21T and the side surfaces 21S of the first support member 22 are covered by a first conductive film 23. The first conductive film 23 functions as an electromagnetic shielding film. The first conductive film 23 may be a continuous film entirely covering a specific area or may be a patterned film configured to function as the electromagnetic shield, such as a reticulated grating film or a striped film. At least one of the first electrodes 31A exposed at the first surface 21A is also exposed at a side surface 21S of the first support member 22 and is coupled electrically to the first conductive film 23.

A resin-made second support member 40 is in contact with at least first surfaces 21A of respective submodules 20 and thereby supports the submodules 20. The first surfaces 21A of respective submodules 20 are supported and positioned so as to face in the same direction. The high-frequency module 50 has a mounting surface 41A that faces in the same direction in which the first surfaces 21A of the submodules 20 face. The second support member 40 includes a top surface 41T facing opposite to the mounting surface 41A and side surfaces 41S connecting the mounting surface 41A and the top surface 41T.

In the submodule 20 having the first conductive film 23, the second support member 40 is adhered to the surface of the first conductive film 23 and the first surface 21A of the first support member 22. In the submodule 20 not having the first conductive film 23, the second support member 40 is adhered to the top surface 21T, the side surfaces 21S, and the first surface 21A of the first support member 22.

Multiple outer terminals 42 are provided so as to be coupled to respective inner terminals 31 and be exposed at the mounting surface 41A. Each outer terminal 42 includes two layers, in other words, a second electrode 42A exposed at the mounting surface 41A and made of copper (Cu) and a solder 42B coupled to a corresponding inner terminal 31. At least one of the outer terminals 42 is coupled to the first conductive film 23 via the first electrode 31A.

In addition to the second electrodes 42A, a first conductor wire 43 is also disposed on the mounting surface 41A. The first conductor wire 43 is coupled to one of the inner terminals 31 of a submodule 20 via a solder 42B and is also coupled to one of the inner terminals 31 of another submodule 20 via another solder 42B. In other words, the first conductor wire 43 couples one of the submodules 20 to another submodule 20. The mounting surface 41A is a substantially flat surface formed of the surfaces of the outer terminals 42, the surface of the first conductor wire 43, and the surface of the second support member 40.

FIG. 1B is a cross-sectional view illustrating the high-frequency module 50 of FIG. 1A and a module substrate 80. Multiple lands 81 are disposed on a surface of the module substrate 80. When the high-frequency module 50 is mounted on the module substrate 80, the outer terminals 42 of the high-frequency module 50 are coupled to respective lands 81 of the module substrate 80 via solder 85. The first conductive film 23 is connected to the ground potential of the module substrate 80 via the first electrode 31A exposed at a side surface 21S of the submodule 20, an outer terminal 42, a solder 85, and a land 81.

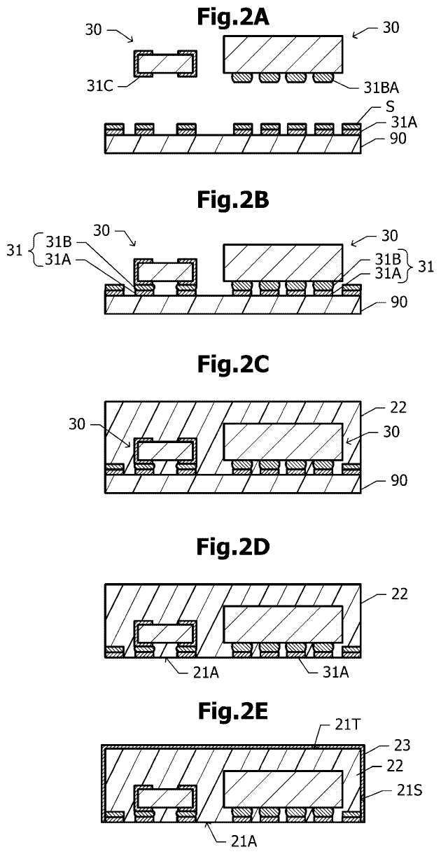

A method of manufacturing the submodule 20 will be described with reference to FIGS. 2A to 2E. FIGS. 2A to 2D are cross-sectional views illustrating a manufacturing process of the submodule 20, and FIG. 2E is a cross-sectional view of the submodule 20.

As illustrated in FIG. 2A, multiple electronic components 30 and a provisional substrate 90 are prepared. A printed-circuit board can be used as the provisional substrate 90. Multiple first electrodes 31A are disposed on the surface of the provisional substrate 90, and solder bumps S are formed on respective first electrodes 31A. Note that FIG. 2A only illustrates a region corresponding to an individual submodule 20 although in reality, submodules 20 are not separated in the step of FIG. 2A. An electronic component 30, such as a semiconductor integrated circuit, has multiple solder balls 31BA to be used for mounting. An electronic component 30, such as a surface-mount type component, has electrodes 31C to be used for mounting.

As illustrated in FIG. 2B, the solder balls 31BA or the electrodes 31C of the electronic components 30 are placed on the corresponding solder bumps S of the provisional substrate 90 and are subjected to reflow treatment. The electronic component 30 is thereby fixed to the provisional substrate 90. The solder balls 31BA and respective solder bumps S are integrated by the reflow treatment, thereby forming the inner terminals 31 each consisting of the solder 31B and the first electrode 31A. In the electronic component 30 having the electrodes 31C, the solder bumps S are melted and solidified again to form the solder 31B. Consequently, each inner terminal 31 is formed of the solder 31B and the first electrode 31A.

As illustrated in FIG. 2C, the first support member 22 is formed by covering the electronic components 30 with a sealing resin. The first support member 22 can be formed, for example, using transfer molding or compression molding. For example, the first support member 22 is made of epoxy resin.

As illustrated in FIG. 2D, the provisional substrate 90 (see FIG. 2C) is ground away to expose the first electrodes 31A. The first support member 22 is exposed where the first electrodes 31A are not present. The flat first surface 21A is thereby formed so as to expose the surface of the first support member 22 and the surfaces of the first electrodes 31A. After grinding, a mother substrate is cut into discrete submodules 20. The submodules 20 without having the first conductive film 23 (i.e., the submodule 20 on the left hand side in FIG. 1A) are completed through the above steps.

As illustrated in FIG. 2E, the first conductive film 23 is formed so as to cover the top surface 21T and the side surfaces 21S of the first support member 22. For example, the first conductive film 23 is made of copper (Cu), silver (Ag), or nickel (Ni). The first conductive film 23 can be formed by laminating layers of different metals. For example, the first conductive film 23 can be formed by sputtering. The submodules 20 having the first conductive film 23 (i.e., the submodule 20 on the right hand side in FIG. 1A) are completed through the above steps.

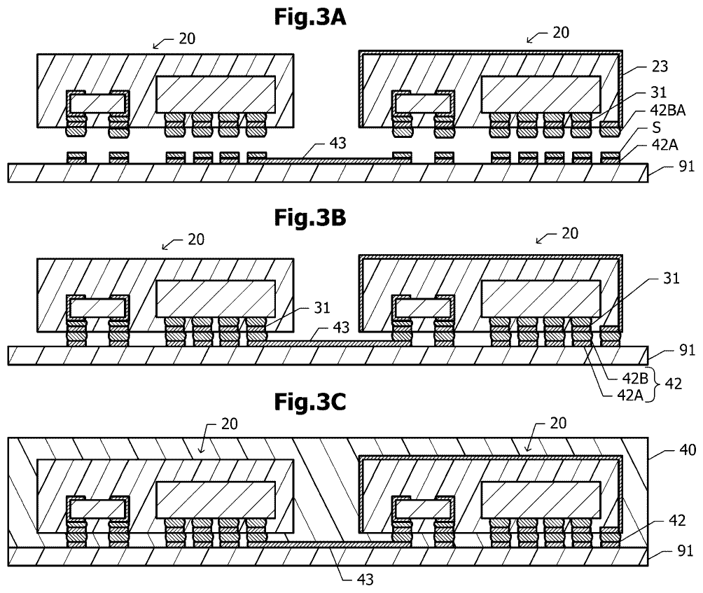

Next, a method of manufacturing the high-frequency module 50 will be described with reference to FIGS. 3A to 3C. FIGS. 3A, 3B, and 3C are cross-sectional views illustrating a manufacturing process of the high-frequency module 50 (see FIG. 1A).

As illustrated in FIG. 3A, a provisional substrate 91, the submodule 20 having the first conductive film 23, and the submodule 20 without having the first conductive film 23 are prepared. Multiple second electrodes 42A and a first conductor wire 43 are disposed on the surface of the provisional substrate 91. Solder bumps S are formed on the second electrodes 42A and on portions of the first conductor wire 43. A printed-circuit board can be used as the provisional substrate 91. Solder balls 42BA are formed on the surfaces of respective exposed inner terminals 31 of the submodule 20.

As illustrated in FIG. 3B, the submodules 20 are placed on the provisional substrate 91 and subjected to the reflow treatment, and the submodules 20 are thereby fixed to the provisional substrate 91. The solder balls 42BA and respective solder bumps S are integrated by the reflow treatment, thereby forming the outer terminals 42 each consisting of the solder 42B and the second electrode 42A. One of the inner terminals 31 of a submodule 20 is coupled to one of the inner terminals 31 of another substrate 20 via a solder 42B, the first conductor wire 43, and another solder 42B.

As illustrated in FIG. 3C, the second support member 40 is formed by sealing multiple submodules 20 with a resin. The second support member 40 can be formed, for example, using transfer molding or compression molding. For example, the second support member 40 is made of epoxy resin.

After the second support member 40 is formed, the provisional substrate 91 is ground away to expose the outer terminals 42, the first conductor wire 43, and the second support member 40. A substantially flat mounting surface 41A is thereby formed so as to expose the surfaces of the outer terminals 42, the surface of the first conductor wire 43, and the surface of the second support member 40. Finally, individual high-frequency modules 50 are separated to complete the high-frequency module 50 illustrated in FIG. 1A.

Next, advantageous effects accordingly to the first exemplary embodiment will be described.

The high-frequency module 50 of the first exemplary embodiment does not include an interposer. In other words, the submodules 20 included in the high-frequency module 50 of the first exemplary embodiment are mounted directly onto the module substrate 80 without using interposers, which leads to the height reduction. At least one of the submodules 20 has the first conductive film 23 covering the top surface 21T and the side surfaces 21S thereof. The first conductive film 23 functions as the electromagnetic shielding film. This can reduce electromagnetic interference between the submodule 20 having the first conductive film 23 and another submodule 20. It is especially preferable that the first conductive film 23 functioning as the electromagnetic shielding film be provided preferentially for a submodule 20 of which the operating frequency is low and the output power is high.

The submodules 20 included in the high-frequency module 50 are coupled to each other by the first conductor wire 43. This eliminates the necessity of the wiring formed inside the module substrate 80 in order to connect the submodules 20. This leads to a reduction in the thickness of the module substrate 80.

Next, different high-frequency modules according to variations of the first exemplary embodiment will be described.

In the first exemplary embodiment, one of the submodules 20 has the first conductive film 23. The first conductive film 23, however, may be provided for all of the submodules 20. In the first exemplary embodiment, the first conductive film 23 entirely covers the top surface 21T and the side surfaces 21S of the first support member 22. The first conductive film 23, however, may cover only part of the top surface 21T and of the side surfaces 21S of the first support member 22. For example, at least one of opposing side surfaces 21S of adjacent submodules 20 may have the first conductive film 23.

In the first exemplary embodiment, the second support member 40 covers the first surface 21A, the side surfaces 21S, and the top surface 21T of each submodule 20. The second support member 40, however, does not need to be provided on the top surface 21T in the case where the second support member 40 can support the submodule 20 stably while the second support member 40 is in contact only with the first surface 21A and the side surfaces 21S of the submodule 20. This configuration can further reduce the height of the high-frequency module 50.

In the first exemplary embodiment, the first conductive film 23 serving as the electromagnetic shielding film is connected to the ground potential of the module substrate 80, for example, via the first electrode 31A exposed at a side surface 21S of the submodule 20. As an alternative configuration, the first conductive film 23 does not need to be connected to the first electrode 31A, thereby leaving the first conductive film 23 in an electrically floating condition. In spite of the electrically floating condition, the first conductive film 23 can still function as the electromagnetic shielding film.

### Second Embodiment

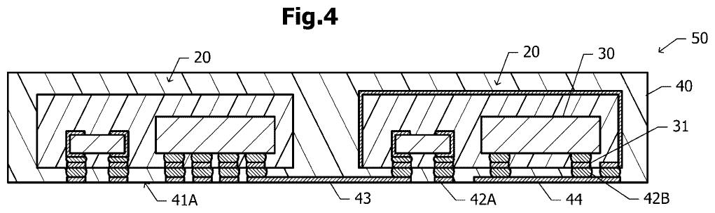

Next, a high-frequency module according to a second exemplary embodiment will be described with reference to FIG. 4. The following will omit the description of the same elements as those of the high-frequency module 50 of the first exemplary embodiment, which has been described with reference to FIGS. 1A to 3C.

FIG. 4 is a cross-sectional view illustrating the high-frequency module 50 according to the second exemplary embodiment. In the first exemplary embodiment (see FIG. 1), the second electrodes 42A and the first conductor wire 43 are disposed on the mounting surface 41A of the high-frequency module 50. On the other hand, in the second exemplary embodiment, patterned conductor traces 44 are also formed on the mounting surface 41A. The patterned conductor traces 44 are connected to the ground potential of the electronic component 30 via the solder 42B and the inner terminals 31. As viewed in plan, the patterned conductor traces 44 are disposed, so as to overlap part of the submodule 20, in an area where necessary wiring, such as signal wiring, control wiring, and power supply wiring, is not present. The patterned conductor traces 44 function as the electromagnetic shielding film for the submodule 20.

Next, advantageous effects according to the second exemplary embodiment are described. In the first exemplary embodiment, the first conductive film 23 disposed on the top surface 21T and the side surfaces 21S of the submodule 20 provides electromagnetic shielding in upward and lateral directions. In the second exemplary embodiment, the patterned conductor traces 44 can provide electromagnetic shielding also in downward direction of the submodule 20.

### Third Embodiment

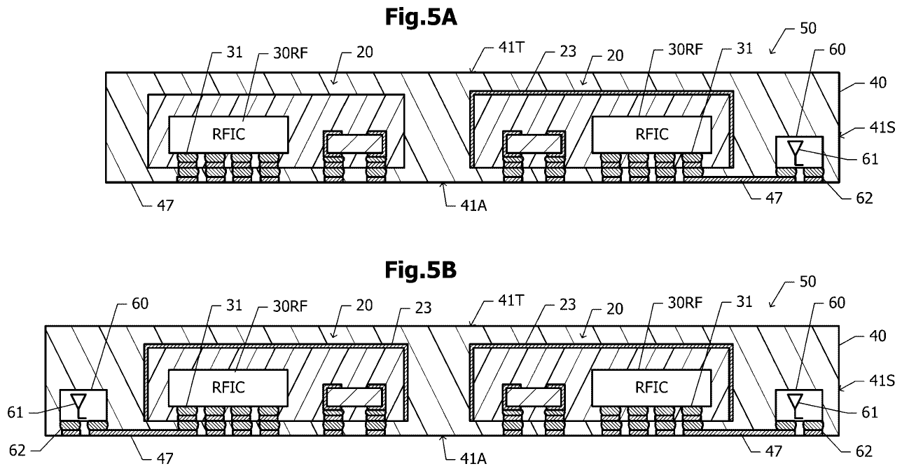

Next, a high-frequency module according to a third exemplary embodiment will be described with reference to FIG. 5A. The following will omit the description of the same elements as those of the high-frequency module 50 of the first exemplary embodiment, which has been described with reference to FIGS. 1A to 3C.

FIG. 5A is a cross-sectional view illustrating a high-frequency module 50 according to the third exemplary embodiment. In the first exemplary embodiment (see FIG. 1A), the second support member 40 supports multiple submodules 20. In the third exemplary embodiment, however, the second support member 40 also supports an antenna component 60 in addition to the submodules 20.

The antenna component 60 includes an antenna element 61 and an antenna terminal 62. For example, a patch antenna or a dipole antenna is used for the antenna element 61. In FIG. 5A, the antenna element 61 is represented by a circuit symbol. The antenna terminal 62 is exposed at the mounting surface 41A of the high-frequency module 50.

Each submodule 20 includes a high-frequency integrated circuit component 30RF (RFIC) as one of the electronic components 30. Each submodule 20 performs high-frequency signal processing, such as down-conversion, up-conversion, or amplification. A second conductor wire 47 is disposed on the mounting surface 41A of the high-frequency module 50. The second conductor wire 47 couples the antenna terminal 62 to an inner terminal 31 of one of the submodules 20. The submodule 20 coupled to the antenna component 60 has the first conductive film 23 serving as the electromagnetic shielding film.

A submodule 20 not coupled to the antenna component 60 is coupled to an antenna disposed outside the high-frequency module 50.

Next, advantageous effects according to the third exemplary embodiment are described.

In the third exemplary embodiment, the antenna component 60 and multiple submodules 20, each having RF front-end functions, are mounted on a single high-frequency module 50. The second conductor wire 47 formed inside the high-frequency module 50 couples the antenna component 60 to one of the submodules 20, which eliminates the necessity of providing an additional feeder line outside the high-frequency module 50. This can reduce the likelihood of the loss of high-frequency signal supplied to the antenna component 60.

In addition, the first conductive film 23, which serves as the electromagnetic shielding film, is formed on the submodule 20 coupled to the antenna component 60, which can reduce electromagnetic interference between the submodule 20 and the antenna component 60 and also between multiple submodules 20.

Next, a high-frequency module according to a variation of the third exemplary embodiment will be described with reference to FIG. 5B. FIG. 5B is a cross-sectional view illustrating a high-frequency module 50 according to the variation of the third exemplary embodiment. In the variation illustrated in FIG. 5B, the high-frequency module 50 includes multiple antenna components 60. Each antenna component 60 is coupled to a corresponding submodule 20 included in the high-frequency module 50 by the second conductor wire 47. As in the case of the present variation, the antenna components 60 may be disposed inside the high-frequency module 50 and coupled to respective submodules 20.

### Fourth Embodiment

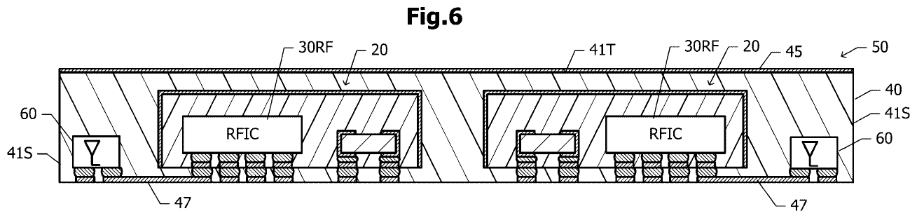

Next, a high-frequency module according to a fourth exemplary embodiment will be described with reference to FIG. 6. The following will omit the description of the same elements as those of the high-frequency module 50 of the variation of the third exemplary embodiment, which has been described with reference to FIG. 5B.

FIG. 6 is a cross-sectional view illustrating a high-frequency module 50 according to the fourth exemplary embodiment. In the variation of the third exemplary embodiment (see FIG. 5B), the top surface 41T and the side surfaces 41S of the second support member 40 are not covered by the conductive film. In the fourth exemplary embodiment, however, a second conductive film 45 covers the top surface 41T of the second support member 40 almost entirely. In other words, as viewed in plan, the antenna component 60 is also covered by the second conductive film 45. Note that the conductive film is not disposed on the side surfaces 41S of the second support member 40. The second conductive film 45 can be formed on the top surface 41T of the second support member 40 using sputtering or the like before separating a mother substrate into discrete high-frequency modules 50.

Next, advantageous effects according to the fourth exemplary embodiment are described.

In the fourth exemplary embodiment, the second conductive film 45 disposed on the top surface 41T of the second support member 40 serves as the electromagnetic shielding film. The second conductive film 45 shields radio waves propagating upward from the antenna component 60 (in the direction in which the top surface 41T of the second support member 40 faces). Radio waves propagating sideways from the antenna component 60 (in the directions in which the side surfaces 41S of the second support member 40 face) radiate outward without being blocked. Accordingly, the high-frequency module 50 of the fourth exemplary embodiment can control the directivity of radio waves. It is effective to adopt the fourth exemplary embodiment in the case of the main beam of the antenna component 60 being directed sideways.

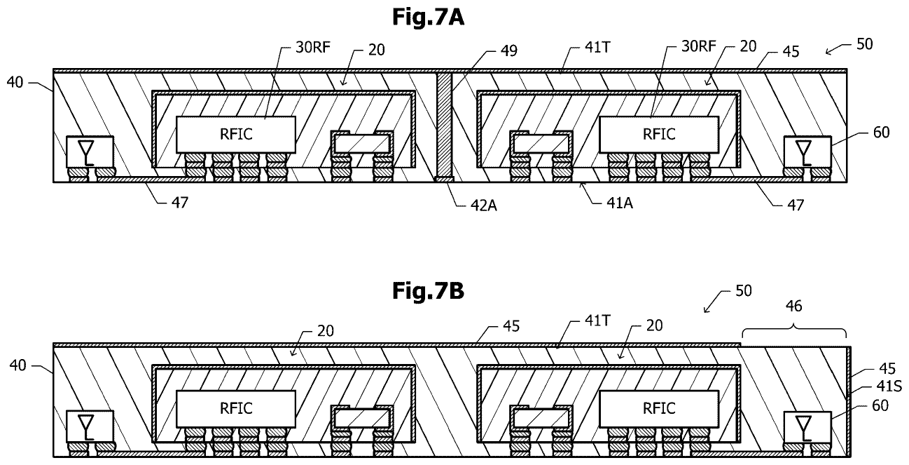

Next, a high-frequency module according to a variation of the fourth exemplary embodiment will be described with reference to FIG. 7A. FIG. 7A is a cross-sectional view illustrating a high-frequency module 50 according to the variation of the fourth exemplary embodiment. In the fourth exemplary embodiment (see FIG. 6), the second conductive film 45 is in an electrically floating condition. In the variation illustrated in FIG. 7A, however, the second conductive film 45 is coupled to a second electrode 42A at the mounting surface 41A using a conductive column 49 that pierces through the second support member 40 in the height direction. The second electrode 42A coupled to the conductive column 49 is further connected to the ground potential inside the high-frequency module 50. The potential of the second conductive film 45 is thereby set to the ground.

Next, a high-frequency modules according to another variation of the fourth exemplary embodiment will be described with reference to FIG. 7B. FIG. 7B is a cross-sectional view illustrating a high-frequency module 50 according to another variation of the fourth exemplary embodiment. In the fourth exemplary embodiment (see FIG. 6), the second conductive film 45 is disposed on the entire area of the top surface 41T of the second support member 40. In the variation illustrated in FIG. 7B, however, a part of the top surface 41T of the second support member 40 is not covered by the second conductive film 45 (hereinafter referred to as an “opening 46 of the second conductive film 45”). In other words, the second conductive film 45 has the opening 46, and a part of the top surface 41T of the second support member 40 is exposed in the opening 46. When the top surface 41T of the second support member 40 is viewed in plan, at least one of the antenna components 60 is disposed so as to overlap the opening 46. In addition, the second conductive film 45 is also disposed on a side surface 41S of the second support member 40 near this antenna component 60.

Next, advantageous effects according to the variation illustrated in FIG. 7B are described. The antenna component 60 is disposed in an area overlapping the opening 46 of the second conductive film 45 as viewed in plan, and this antenna component 60 emits radio waves upward and outward through the opening 46. It is effective to adopt the variation illustrated in FIG. 7B in the case where the antenna component 60 is disposed in the area overlapping the opening 46, and the main beam of the antenna component 60 is directed upward.

### Fifth Embodiment

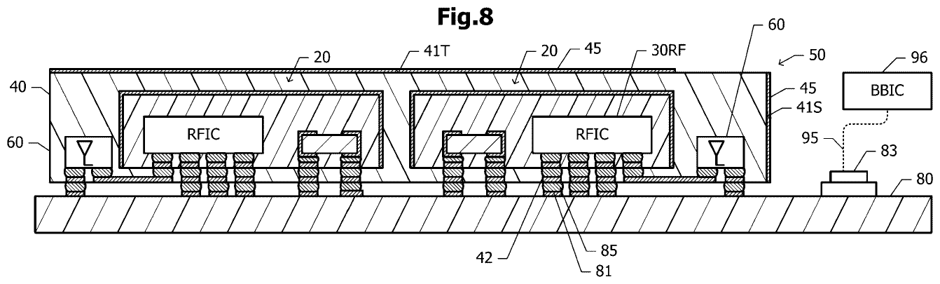

Next, a high-frequency module according to a fifth exemplary embodiment will be described with reference to FIG. 8. The following will omit the description of the same elements as those of the high-frequency module 50 of the first exemplary embodiment, which has been described with reference to FIGS. 1A to 3C.

FIG. 8 is a cross-sectional view illustrating a high-frequency module 50 and a module substrate 80 according to the fifth exemplary embodiment. The high-frequency module 50 of the eighth exemplary embodiment includes multiple antenna components 60, as does the high-frequency module 50 of the variation of the fourth exemplary embodiment illustrated in FIG. 7B. In addition, the high-frequency module 50 has the second conductive film 45 disposed in some areas of the top surface 41T and the side surfaces 41S of the second support member 40. Moreover, the module substrate 80 has a connector 83 for high-frequency waves mounted thereon. More specifically, the second conductive film 45 covers a side surface 41S of the second support member 40, the side surface 41S facing the connector 83.

For example, the connector 83 is coupled to a baseband integrated circuit component 96 (BBIC) using a coaxial cable 95. The connector 83 is also coupled to an outer terminal 42 of a submodule 20 via a conductor wire (not illustrated) formed inside the module substrate 80, a land 81, and a solder 85. This submodule 20 includes the high-frequency integrated circuit component 30RF as an electronic component 30. Signals, such as intermediate-frequency signals and various control signals, are transmitted between the baseband integrated circuit component 96 and the submodule 20 via the connector 83 and the coaxial cable 95.

Next, advantageous effects according to the fifth exemplary embodiment are described.

The second conductive film 45 disposed on the side surface 41S of the second support member 40 facing the connector 83 serves as the electromagnetic shielding film. This improves the isolation between the connector 83 and the high-frequency circuit inside the high-frequency module 50.

### Sixth Embodiment

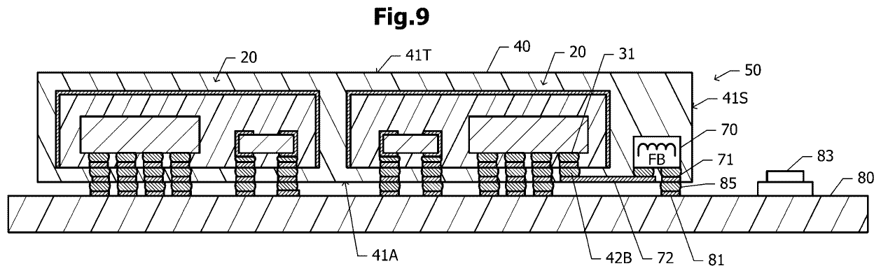

Next, a high-frequency module according to a sixth exemplary embodiment will be described with reference to FIG. 9. The following will omit the description of the same elements as those of the high-frequency module 50 of the first exemplary embodiment, which has been described with reference to FIGS. 1A to 3C.

FIG. 9 is a cross-sectional view illustrating a high-frequency module 50 and a module substrate 80 according to the sixth exemplary embodiment. In the first exemplary embodiment (see FIG. 1A), the second support member 40 supports multiple submodules 20. In the sixth exemplary embodiment, however, the second support member 40 also supports a surface-mount chip component 70 in addition to the submodules 20. Outer terminals 71 of the chip component 70 are exposed at the mounting surface 41A of the high-frequency module 50. Examples of the chip component 70 include a surface-mount ferrite bead, a surface-mount inductor, and a surface-mount bypass capacitor. FIG. 9 illustrates a ferrite bead as an example of the chip component 70. The chip component 70, however, is not limited to the ferrite bead.

As is the case in the fifth exemplary embodiment (see FIG. 8), the connector 83 is mounted on the module substrate 80. The connector 83 is coupled to one of the outer terminals 71 of the chip component 70 via a conductor wire (not illustrated) formed inside the module substrate 80, a land 81, and a solder 85. Another outer terminal 71 of the chip component 70 is coupled to one of the inner terminals 31 of a submodule 20 via a conductor wire 72 disposed on the mounting surface 41A and a solder 42B. High-frequency signals are transmitted between the connector 83 and the submodule 20 through the chip component 70. As viewed in plan, the chip component 70 is disposed at a position between the connector 83 and the submodule 20 to which the chip component 70 is coupled.

Next, advantageous effects according to the sixth exemplary embodiment are described.

In the case of the chip component 70 being the ferrite bead, the chip component 70 is generally disposed in the vicinity of the connector 83. In other words, as viewed in plan, no component is present between the chip component 70 and the connector 83, and the chip component 70 and the connector 83 are positioned next to each other. Provision of the chip component 70 or the ferrite bead inside the high-frequency module 50 leads to space saving compared with a case in which the ferrite bead is disposed on the module substrate 80 outside the high-frequency module 50.

In the case in which a chip component 70 is mounted on the module substrate 80 instead of providing the chip component 70 inside the high-frequency module 50, a minimum inter-component distance needs to be provided between the connector 83 and the chip component and also between the chip component and the high-frequency module 50. The condition of the minimum inter-component distance needs to be satisfied in the mounting step. In the sixth exemplary embodiment, however, the chip component 70 is built in the high-frequency module 50. Accordingly, only the distance between the connector 83 and the high-frequency module 50 needs to be taken into account in order to satisfy the minimum inter-component distance in the mounting step. This leads space saving.

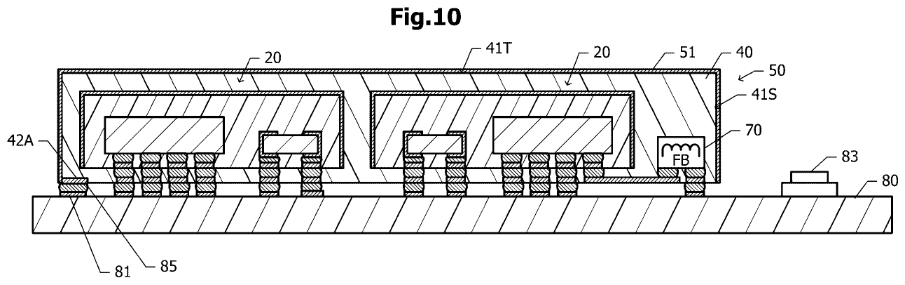

Next, a high-frequency module according to a variation of the sixth exemplary embodiment will be described with reference to FIG. 10. FIG. 10 is a cross-sectional view illustrating a high-frequency module 50 and a module substrate 80 according to the variation of the sixth exemplary embodiment.

In the sixth exemplary embodiment (see FIG. 9), the top surface 41T and the side surfaces 41S of the second support member 40 are not covered by the conductive film. In the variation illustrated in FIG. 10, however, a third conductive film 51 covers the top surface 41T and the side surfaces 41S of the second support member 40. The third conductive film 51 is connected to the ground potential of the module substrate 80 via a second electrode 42A exposed at a side surface 41S of the second support member 40, a solder 85, and a land 81.

In the variation illustrated in FIG. 10, the third conductive film 51 functions as the electromagnetic shielding film, which improves the isolation between the connector 83 and the high-frequency circuit inside the high-frequency module 50. This can reduce the likelihood of the high-frequency circuit inside the high-frequency module 50 receiving the noises generated at the connector 83. This also can reduce the likelihood of the noises generated inside the high-frequency module 50 escaping outside.

### Seventh Embodiment

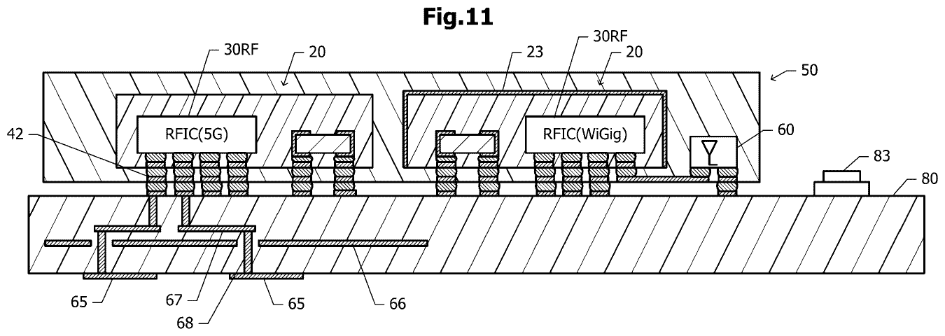

Next, a high-frequency module according to a seventh exemplary embodiment will be described with reference to FIG. 11. The following will omit the description of the same elements as those of the high-frequency module 50 of the variation of the third exemplary embodiment (see FIG. 5B).

FIG. 11 is a cross-sectional view illustrating a high-frequency module 50 and a module substrate 80 according to the seventh exemplary embodiment. In the third exemplary embodiment (see FIG. 5B), the second support member 40 supports two antenna components 60 coupled to respective submodules 20, each containing the high-frequency integrated circuit component 30RF. In the seventh exemplary embodiment, the antenna component 60 is disposed in the second support member 40, and radiating elements 65 are disposed on the module substrate 80.

The radiating elements 65 are disposed on a surface of the module substrate 80, the surface being opposite to the surface on which the high-frequency module 50 is mounted. The radiating elements 65 and a ground plane 66 disposed inside the module substrate 80 form a patch antenna. Each radiating element 65 is coupled to a corresponding outer terminal 42 of a submodule 20 via a conductor wire 67 and a conductive via 68 formed inside the module substrate 80.

For example, the high-frequency integrated circuit component 30RF included in the submodule 20 coupled to the antenna component 60 performs signal processing in accordance with the WiGig standard. On the other hand, the high-frequency integrated circuit component 30RF included in the submodule 20 coupled to the radiating elements 65 performs signal processing in accordance with the telecommunication protocols for the 5th generation mobile communication system (i.e., 5G). The first conductive film 23 covers the submodule 20 performing signal processing in accordance with the WiGig standard.

Next, advantageous effects according to the seventh exemplary embodiment are described.

The high-frequency module 50 of the seventh exemplary embodiment can perform telecommunication in accordance with different protocols, such as WiGig and 5G. Providing at least one of the two submodules 20 with the first conductive film 23 serving as the electromagnetic shielding film ensures the isolation between the two submodules 20 operating in accordance with different telecommunication protocols.

The antenna component 60 inside the high-frequency module 50 serves as one of the two antennas operating with different telecommunication protocols, and the radiating elements 65 disposed on the module substrate 80 serve as the other antenna. Accordingly, the suitably configured antennas that can operate in different frequency bands for different telecommunication protocols are available for use.

### Eighth Embodiment

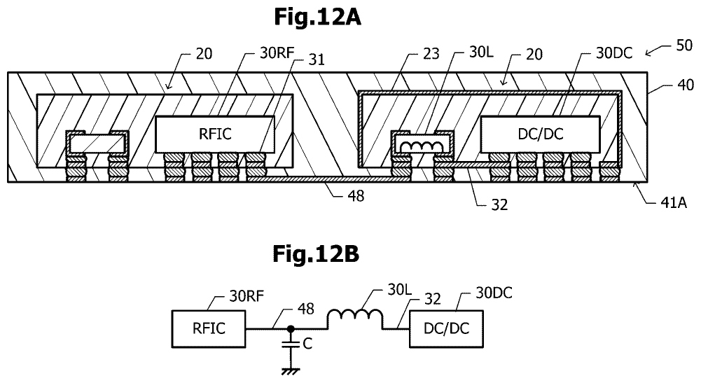

Next, a high-frequency module according to an eighth exemplary embodiment will be described with reference to FIGS. 12A and 12B. The following will omit the description of the same elements as those of the high-frequency module 50 of the first exemplary embodiment, which has been described with reference to FIGS. 1A to 3C.

FIG. 12A is a cross-sectional view illustrating a high-frequency module 50 according to the eighth exemplary embodiment, and FIG. 12B is a schematic equivalent circuit diagram of the high-frequency module 50 of the eighth exemplary embodiment. The high-frequency module 50 includes two submodules 20. One of the submodules 20 includes a DC-DC converter 30DC and an output inductor 30L as the electronic components 30. The output inductor 30L is coupled to the DC-DC converter 30DC via a conductor wire 32 formed inside the submodule 20. The first conductive film 23 serving as the electromagnetic shielding film is disposed on the submodule 20 having the DC-DC converter 30DC.

The other submodule 20 includes the high-frequency integrated circuit component 30RF as the electronic component 30. The output inductor 30L is coupled to an inner terminal 31 of the high-frequency integrated circuit component 30RF via a third conductor wire 48 disposed on the mounting surface 41A of the high-frequency module 50.

As illustrated in FIG. 12B, the output inductor 30L and a capacitor C form a low-pass filter. For example, the capacitor C is included in the submodule 20 having the output inductor 30L. The DC-DC converter 30DC supplies power to the high-frequency integrated circuit component 30RF via the low-pass filter.

The output inductor 30L is disposed at a position closer than any other electronic component in the same submodule 20 to the other submodule 20 coupled using the third conductor wire 48.

Next, advantageous effects according to the eighth exemplary embodiment are described.

The first conductive film 23 is disposed on the submodule 20 having the DC-DC converter 30DC, which can reduce the likelihood of the high-frequency integrated circuit component 30RF receiving the switching noise generated by the DC-DC converter 30DC. In addition, the output inductor 30L is disposed near the submodule 20 having the high-frequency integrated circuit component 30RF, which can improve the quality of the power supplied to the high-frequency integrated circuit component 30RF and also can reduce the occurrence of voltage drop.

Next, a variation of the eighth exemplary embodiment is described.

In the eighth exemplary embodiment, the low-pass filter is formed of the output inductor 30L and the capacitor C. However, the low-pass filter that can reduce the noise may be formed of other elements with different circuit configurations. For example, a condenser or a ferrite bead may be used in place of the output inductor 30L. For example, instead of coupling the output inductor 30L in series between the high-frequency integrated circuit component 30RF and the DC-DC converter 30DC, an inductor may be coupled between the ground and a conductor wire that connects the DC-DC converter 30DC to the high-frequency integrated circuit component 30RF.

### Ninth Embodiment

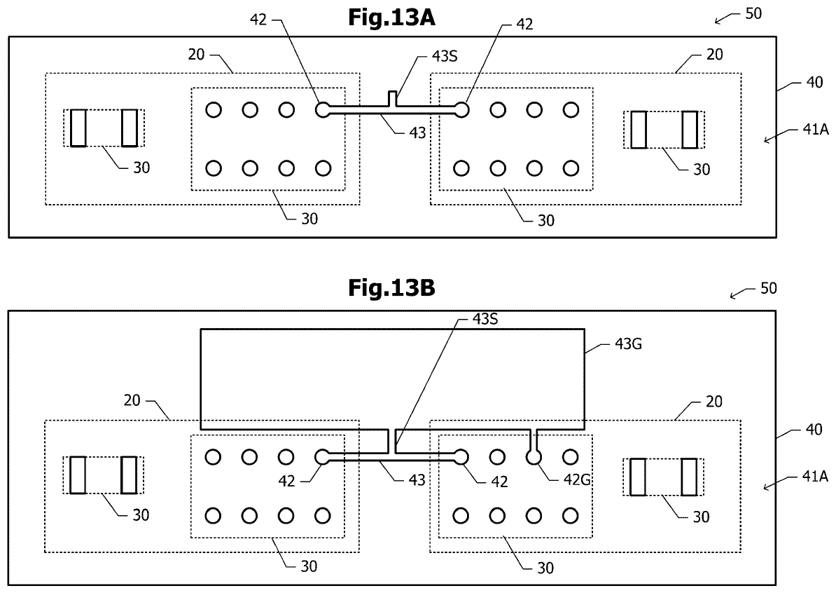

Next, a high-frequency module according to a ninth exemplary embodiment will be described with reference to FIG. 13A. The following will omit the description of the same elements as those of the high-frequency module 50 of the first exemplary embodiment, which has been described with reference to FIGS. 1A to 3C.

FIG. 13A is a bottom view illustrating a high-frequency module 50 according to the ninth exemplary embodiment. In the high-frequency module 50, multiple outer terminals 42 are exposed at the mounting surface 41A of the second support member 40. The first conductor wire 43 couples an outer terminal 42 of an electronic component 30 in one of the submodules 20 to an outer terminal 42 of an electronic component 30 of the other one of the submodules 20. In addition, a stub 43S is branched from the first conductor wire 43. The stub 43S is disposed on the mounting surface 41A of the second support member 40. The stub 43S is an open stub.

FIG. 13B is a bottom view illustrating a high-frequency module 50 according to a variation of the ninth exemplary embodiment. In the ninth exemplary embodiment (see FIG. 13A), the stub 43S branched from the first conductor wire 43 is an open stub. On the other hand, in the variation of the ninth exemplary embodiment illustrated in FIG. 13B, the stub 43S is a shorted stub. A ground plane 43G is formed on the mounting surface 41A of the second support member 40, and the end of the stub 43S is coupled to the ground plane 43G. The ground plane 43G is also coupled to an outer terminal 42G of at least one of the electronic components 30, the outer terminal 42G being coupled further to the ground terminal of at least one of the electronic components 30.

Next, advantageous effects according to the ninth exemplary embodiment and the variation thereof are described.

In the ninth exemplary embodiment, as is the case in the first exemplary embodiment, the height of the high-frequency module can be reduced. In addition, the electromagnetic interference between the submodules 20 also can be reduced.

In the ninth exemplary embodiment and also in the variation thereof, the stub 43S can contribute to the impedance matching between the two submodules 20. The stub 43S can be formed on the mounting surface 41A of the second support member 40 simultaneously with the first conductor wire 43. Accordingly, an impedance matching circuit can be formed without providing an additional circuit component for impedance matching.

### Tenth Embodiment

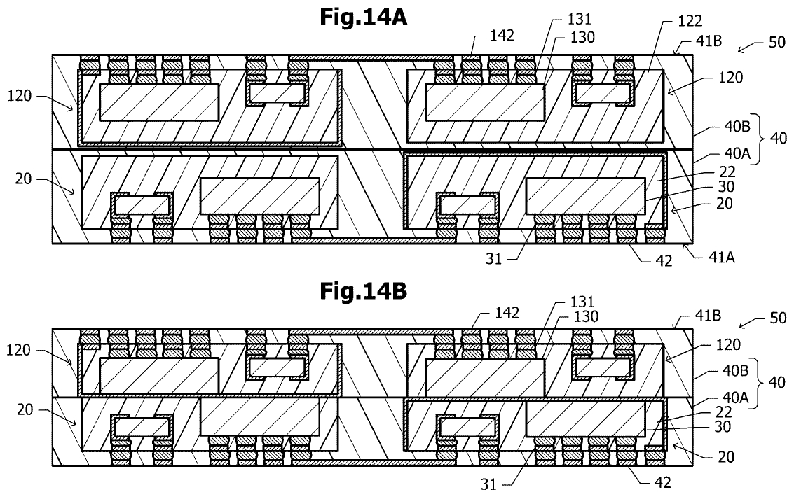

Next, a high-frequency module according to a tenth exemplary embodiment will be described with reference to FIG. 14A. The following will omit the description of the same elements as those of the high-frequency module 50 of the first exemplary embodiment, which has been described with reference to FIGS. 1A to 3C.

FIG. 14A is a cross-sectional view illustrating a high-frequency module 50 according to the tenth exemplary embodiment. The high-frequency module 50 of the tenth exemplary embodiment includes multiple second submodules 120 in addition to multiple submodules 20. In order to distinguish the submodules 20 from the second submodules 120 clearly, the submodules 20 is hereinafter referred to as the “first submodules 20”.

Each second submodule 120 includes multiple second electronic components 130 and a third support member 122 that covers and supports the second electronic components 130. Multiple second inner terminals 131 are coupled to the second electronic components 130 and exposed at one surface of the third support member 122. The surface of the third support member 122 at which the second inner terminals 131 are exposed faces opposite to the surface of the first support member 22 at which the inner terminals 31 are exposed.

The second support member 40 includes a first portion 40A and a second portion 40B. The first portion 40A covers and supports the first submodules 20, and the second portion 40B covers and supports the second submodules 120. Multiple second outer terminals 142 are exposed at a surface 41B of the second support member 40 that faces opposite to the mounting surface 41A thereof at which multiple outer terminals 42 are exposed. The second outer terminals 142 are coupled to respective second inner terminals 131.

The structure formed of the first portion 40A of the second support member 40, the first submodules 20, and the outer terminals 42 is the same as the structure of the high-frequency module 50 of the first exemplary embodiment (see FIG. 1A). In addition, the structure formed of the second portion 40B of the second support member 40, the second submodules 120, and the second outer terminals 142 is also the same as the structure of the high-frequency module 50 of the first exemplary embodiment (see FIG. 1A).

Next, a method of manufacturing the high-frequency module of the tenth exemplary embodiment will be described.

The structure that includes the first portion 40A of the second support member 40, the first submodules 20 supported by the first portion 40A, and the outer terminals 42 is prepared using a method similar to the method of manufacturing the high-frequency module 50 of the first exemplary embodiment. The structure that includes the second portion 40B of the second support member 40, the second submodules 120 supported by the second portion 40B, and the second outer terminals 142 is also prepared using the similar method. Subsequently, the first portion 40A and the second portion 40B of the second support member 40 are adhered to each other to produce the high-frequency module of the tenth exemplary embodiment.

Next, advantageous effects according to the tenth exemplary embodiment are described. In the tenth exemplary embodiment, as is the case in the first exemplary embodiment, the height of the high-frequency module can be reduced. In addition, the electromagnetic interference between the first submodules 20 and the second submodules 120 also can be reduced. In addition, in the tenth exemplary embodiment, the first submodules 20 are stacked over the second submodules 120 in the direction orthogonal to the mounting surface 41A, which can increase the mounting density of the electronic components 30 and the second electronic components 130.

Next, a variation of the tenth exemplary embodiment will be described.

In the tenth exemplary embodiment, multiple second submodules 120 are disposed in the second portion 40B of the second support member 40. However, a single second submodule 120 may be disposed in the second portion 40B of the second support member 40. In the tenth exemplary embodiment, at least one of the first submodules 20 has the first conductive film 23 serving as the shielding film (see FIG. 1A). The second submodules 120, however, do not need to include the conductive film serving as the shielding film.

Next, a high-frequency module according to another variation of the tenth exemplary embodiment will be described with reference to FIG. 14B. FIG. 14B is a cross-sectional view illustrating a high-frequency module according to the variation of the tenth exemplary embodiment. In the tenth exemplary embodiment (see FIG. 14A), the second support member 40 is present between the first submodules 20 and the second submodules 120.

On the other hand, in the variation illustrated in FIG. 14B, a top surface of each first submodule 20 opposes a top surface of the corresponding second submodule 120 without the second support member 40 being interposed. Where the top surface of the first submodule 20 is the surface opposite to the surface at which plurality of the inner terminals 31 are disposed. And the top surface of the second submodule 120 is the surface opposite to the surface at which plurality of the second inner terminals 131 are disposed. In this case, for example, an adhesive layer is disposed between these top surfaces.

For example, this structure can be manufactured in the following manner. A structure as illustrated in FIG. 3B is prepared in the process of the manufacturing the high-frequency module 50 of the first exemplary embodiment. Subsequently, the structure is sealed with resin by transfer molding in such a manner that the top surface of at least one of the first submodules 20 is exposed. Alternatively, after the first submodules 20 are sealed with the second support member 40 as illustrated in FIG. 3C, the second support member 40 is ground or polished away so as to expose the top surfaces of the first submodules 20. The structure covered with the second portion 40B of the second support member 40 can be prepared in the similar manner.

In the variation illustrated in FIG. 14B, the height of the high-frequency module can be further reduced compared with that of the tenth exemplary embodiment.

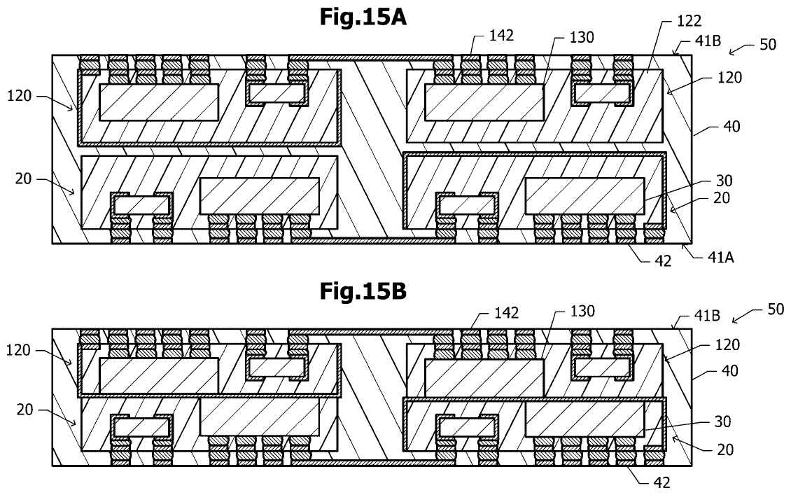

Next, high-frequency modules according to other variations of the tenth exemplary embodiment will be described with reference to FIGS. 15A and 15B. FIGS. 15A and 15B are cross-sectional views illustrating high-frequency modules 50 according to other variations of the tenth exemplary embodiment.

In the tenth exemplary embodiment (see FIG. 14A), the first portion 40A of the second support member 40 supports the first submodules 20, and the second portion 40B of the second support member 40 supports the second submodules 120, and the boundary between the first portion 40A and the second portion 40B appears clearly. On the other hand, in the variations illustrated in FIGS. 15A and 15B, the second support member 40 is formed as a single resin member.

The following describes a method of manufacturing the high-frequency module 50 of the variation illustrated in FIG. 15A. In the step illustrated in FIG. 3B in the process of the manufacturing the high-frequency module 50 of the first exemplary embodiment, a provisional substrate 91 on which the first submodules 20 are mounted and another provisional substrate 91 on which the second submodules 120 are mounted are placed together with respective mounting surfaces facing each other. Subsequently, in this state, the void between the two provisional substrates 91 is filled with the material of the second support member 40 using transfer molding. The provisional substrates 91 are ground away to produce the high-frequency module of the variation illustrated in FIG. 15A.

In the high-frequency module 50 according to the variation illustrated in FIG. 15B, the second support member 40 is not present between the top surfaces of the first submodules 20 and the top surfaces of the second submodules 120 as is the case in the variation illustrated in FIG. 14B. For example, the top surfaces of the first submodule 20 are in contact with respective top surfaces of the second submodules 120. The high-frequency module of the variation illustrated in FIG. 15B can be manufactured such that the top surfaces of the second submodules 120 are placed on the top surfaces of the first submodules 20 so as to be in contact with each other when the void between the two provisional substrates 91 is filled with the material of the second support member 40 using transfer molding.

In the variations illustrated in FIGS. 15A and 15B, the number of steps in the manufacturing process can be reduced compared with the tenth exemplary embodiment (see FIG. 14A).

Note that the exemplary embodiments described herein are examples and configurations described in different exemplary embodiments can be partially replaced or combined with one another. The similar advantageous effects derived from the similar configurations of different exemplary embodiments have not been repeated. The exemplary embodiments are not intended to limit the present disclosure. It is apparent that for example, various alterations, modifications, and different combinations can be made easily by those skilled in the art.

### REFERENCE SIGNS LIST

20 submodule
21A first surface
21S side surface
21T top surface
22 first support member
23 first conductive film
30 electronic component
30DC DC-DC converter
30L output inductor
30RF high-frequency integrated circuit component
31 inner terminal
31A first electrode
31B solder
31BA solder ball
31C electrode for mounting
32 conductor wire
40 second support member
40A first portion of second support member
40B second portion of second support member
41A mounting surface
41S side surface
41T top surface
42 outer terminal
42A second electrode
42B solder
42BA solder ball
42G outer terminal coupled to ground terminal
43 first conductor wire
43G ground plane
43S stub
44 patterned conductor traces
45 second conductive film
46 opening
47 second conductor wire
48 third conductor wire
49 conductive column
50 high-frequency module
51 third conductive film
60 antenna component
61 antenna element
62 antenna terminal
65 radiating element
66 ground plane
67 conductor wire
68 conductive via
70 ferrite bead
71 outer terminal of ferrite bead
72 conductor wire
80 module substrate
81 land
83 connector
85 solder
90, 91 provisional substrate
95 coaxial cable
96 baseband integrated circuit component
120 second submodule
122 third support member
130 second electronic component
131 second inner terminal
142 second outer terminal

1. A high-frequency module comprising:
submodules, each including
electronic components, each including inner terminals, and
a first support member to cover and support the electronic components to expose the inner terminals;
a second support member to cover and support the submodules; and
outer terminals coupled to respective ones of the inner terminals and exposed from the second support member, wherein
at least one of the submodules includes a first conductive film formed on at least part of the first support member.

2. The high-frequency module according to claim 1, wherein
a surface of the first support member at which the inner terminals of each one of the submodule are exposed and a surface of the second support member at which the outer terminals are exposed face in a same direction.

3. The high-frequency module according to claim 1, wherein
each one of the submodules includes the first conductive film.

4. The high-frequency module according to claim 1, further comprising:
a first conductor wire disposed at the surface of the second support member at which the outer terminals are exposed, the first conductor wire configured to couple one of the inner terminals of one of the submodules to one of the inner terminals of another one of the submodules.

5. The high-frequency module according to claim 4, further comprising:
a stub branched from the first conductor wire and disposed on the surface of the second support member at which the outer terminals are exposed.

6. The high-frequency module according to claim 1, further comprising:
at least one antenna component covered and supported by the second support member and including an antenna element and an antenna terminal exposed from the second support member.

7. The high-frequency module according to claim 6, wherein
the second support member includes a top surface facing opposite to the surface at which the outer terminals are exposed, and
the second support member includes a second conductive film disposed on the top surface.

8. The high-frequency module according to claim 7, wherein
a part of the top surface of the second support member is exposed from the second conductive film, and
the at least one antenna component is positioned to overlap the part of the top surface of the second support member when the top surface of the second support member is viewed in plan.

9. The high-frequency module according to claim 6, further comprising:
a second conductor wire disposed at the surface of the second support member at which the outer terminals are exposed, the second conductor wire configured to couple the antenna terminal to one of the inner terminals of one of the submodules, wherein
the one of the submodules coupled to the second conductor wire includes a high-frequency integrated circuit component serving as one of the electronic components.

10. The high-frequency module according to claim 6, wherein
at least two of the submodules include respective high-frequency integrated circuit components configured to perform different signal processing in accordance with different telecommunication protocols, each one of the high-frequency integrated circuit components being one of the electronic components in the corresponding submodule.

11. The high-frequency module according to claim 1, wherein
one of the submodules includes a DC-DC converter and an output inductor coupled to the DC-DC converter, the DC-DC converter and the output inductor being ones of the electronic components,
the high-frequency module further comprises a third conductor wire disposed at the surface of the second support member at which the outer terminals are exposed, the third conductor wire configured to couple the output inductor to one of the inner terminals of one of the submodules that is different from the submodule including the output inductor, and
the output inductor is disposed at a position closer than any other electronic components in the submodule including the output inductor to the submodule to which the third conductor wire is coupled.

12. The high-frequency module according to claim 1, further comprising:
a module substrate including lands coupled to respective ones of the outer terminals; and
a connector mounted on the module substrate.

13. The high-frequency module according to claim 12, further comprising:
at least one surface-mount chip component supported by the second support member and including a terminal exposed at the surface of the second support member at which the outer terminals are exposed, wherein
the chip component is coupled to one of the submodules, and
as viewed in plan, the chip component is disposed between the connector and the submodule to which the chip component is coupled.

14. The high-frequency module according to claim 1, further comprising:
a third conductive film disposed on surfaces of the second support member, the surfaces being different from the surface at which the outer terminals are exposed.

15. The high-frequency module according to claim 1, further comprising:
at least one second submodule, wherein
the at least one second submodule includes
second electronic components, each including second inner terminals,
a third support member to cover and support the second electronic components to expose the second inner terminals, and
second outer terminals coupled to respective ones of the second inner terminals, and
the second support member supports the at least one second submodule in such a manner that the second outer terminals are exposed at a surface of the second support member opposite to the surface at which the outer terminals are exposed.

16. The high-frequency module according to claim 15, wherein
the second support member includes a first portion covering the submodules and a second portion covering the at least one second submodule, and
the first portion is adhered to the second portion.

17. The high-frequency module according to claim 15, wherein
a surface of at least one of the submodules, the surface being opposite to the surface at which the inner terminals are disposed, opposes a surface of the at least one second submodule, the surface being opposite to the surface at which the second inner terminals are disposed, without the second support member being interposed therebetween.

18. The high-frequency module according to claim 16, wherein
a surface of at least one of the submodules, the surface being opposite to the surface at which the inner terminals are disposed, opposes a surface of the at least one second submodule, the surface being opposite to the surface at which the second inner terminals are disposed, without the second support member being interposed therebetween.

19. The high-frequency module according to claim 7, wherein
at least two of the submodules include respective high-frequency integrated circuit components configured to perform different signal processing in accordance with different telecommunication protocols, each one of the high-frequency integrated circuit components being one of the electronic components in the corresponding submodule.

20. The high-frequency module according to claim 8, wherein
at least two of the submodules include respective high-frequency integrated circuit components configured to perform different signal processing in accordance with different telecommunication protocols, each one of the high-frequency integrated circuit components being one of the electronic components in the corresponding submodule.
